(19) United States
(12) Patent Application Publication
(10) Pub. No.: US 2024/0419077 A1
(43) Pub. Date: Dec. 19, 2024

(54) COATING PROCESSING APPARATUS AND METHOD FOR FORMING COATING FILM

(71) Applicant: Kioxia Corporation, Tokyo (JP)

(72) Inventor: Tomoya AKAZAWA, Yokkaichi (JP)

(73) Assignee: Kioxia Corporation, Tokyo (JP)

(21) Appl. No.: 18/740,673

(22) Filed: Jun. 12, 2024

(30) Foreign Application Priority Data
Jun. 19, 2023 (JP) 2023-099940

(51) Int. Cl. G03F 7/16; B05C 5/02; B05C 13/00; H01L 21/66

(52) U.S. Cl. CPC G03F 7/162; B05C 5/02; B05C 13/00; H01L 22/26

(57) ABSTRACT

According to one embodiment, a coating processing apparatus includes a rotary table being rotatable while holding a substrate on which a coating film is to be formed; a first discharge part discharging a first coating liquid to a first discharge position that is a central portion of the substrate to form a first liquid film; a second discharge part discharging a second coating liquid to a second discharge position outside the first discharge position of the substrate to form a second liquid film; an imaging device configured to image contours of the first and second liquid films spreading outside the substrate by rotation of the substrate; and a control device configured to control at least one of a rotation speed of the substrate and the second discharge position based on an imaging result by the imaging device so that a distance between the contours falls within a predetermined range.

### CROSS-REFERENCE TO RELATED APPLICATIONS

This application is based upon and claims the benefit of priority from Japanese Patent Application No. 2023-099940, filed on Jun. 19, 2023; the entire contents of which are incorporated herein by reference.

### FIELD

Embodiments described herein relate generally to a coating processing apparatus and a method for forming a coating film.

### BACKGROUND

One of manufacturing steps of a semiconductor device is a step of applying a chemical liquid onto a substrate to form a coating film. The chemical liquid supplied to the vicinity of the center of the substrate is spread on the substrate by rotation, and unnecessary chemical liquid is discharged to the outside of the substrate. In such a step, to reduce consumption of the chemical liquid, a process for enhancing fluidity of the chemical liquid may be performed by spreading a solvent on the substrate immediately before the chemical liquid is supplied.

Here, the solvent may be dried on an outer peripheral portion of the substrate. Therefore, fluidity of the chemical liquid in the outer peripheral portion of the substrate may not be sufficiently enhanced to cause coating failure.

### BRIEF DESCRIPTION OF THE DRAWINGS

FIG. 1 is a cross-sectional view illustrating an example of a state in which a substrate is placed on a coating processing apparatus according to a first embodiment;

FIGS. 2A to 2B are top views illustrating an example of a state in which the substrate is placed on the coating processing apparatus according to the first embodiment;

FIG. 3 is a block diagram illustrating an example of a hardware configuration of a control device according to the first embodiment;

FIG. 4 is a block diagram illustrating an example of a functional configuration of the control device according to the first embodiment;

FIG. 5 is a diagram illustrating an example of a recipe table included in the control device according to the first embodiment;

FIG. 6 is a diagram illustrating an example of reference information DB stored in a storage unit according to the first embodiment;

FIG. 7 is a flowchart for explaining a flow of a coating film forming process according to the first embodiment;

FIGS. 8A to 8D are diagrams for explaining a flow of the coating film forming process in a processor of the first embodiment;

FIGS. 9A to 9C are top views illustrating an example of a state in which a substrate is placed on a coating processing apparatus according to a modification of the first embodiment;

FIG. 10 is a block diagram illustrating an example of a functional configuration of a control device according to a second embodiment;

FIG. 11 is a diagram illustrating an example of reference information DB stored in a storage unit according to the second embodiment;

FIG. 12 is a flowchart for explaining a flow of a coating film forming process according to the second embodiment; and

FIGS. 13A to 13C are diagrams for explaining a flow of a coating film forming process in a processor of a comparative example.

### DETAILED DESCRIPTION

In general, according to one embodiment, a coating processing apparatus includes: a rotary table that is rotatable while holding a substrate on which a coating film is to be formed; a first discharge part that discharges a first coating liquid to a first discharge position that is a central portion of the substrate held on the rotary table to form a first liquid film; a second discharge part that discharges a second coating liquid to a second discharge position outside the first discharge position of the substrate to form a second liquid film; an imaging device configured to be able to image contours of the first and second liquid films spreading toward an outside of the substrate by rotation of the substrate; and a control device configured to control at least one of a rotation speed of the substrate and the second discharge position based on an imaging result by the imaging device so that a distance between the contours falls within a predetermined range.

Exemplary embodiments of a coating processing apparatus and a method for forming a coating film will be described below in detail with reference to the accompanying drawings. The present invention is not limited to the following embodiments. In addition, constituent elements in the following embodiments include elements that can be easily assumed by a person skilled in the art or elements that are substantially the same.

### First Embodiment

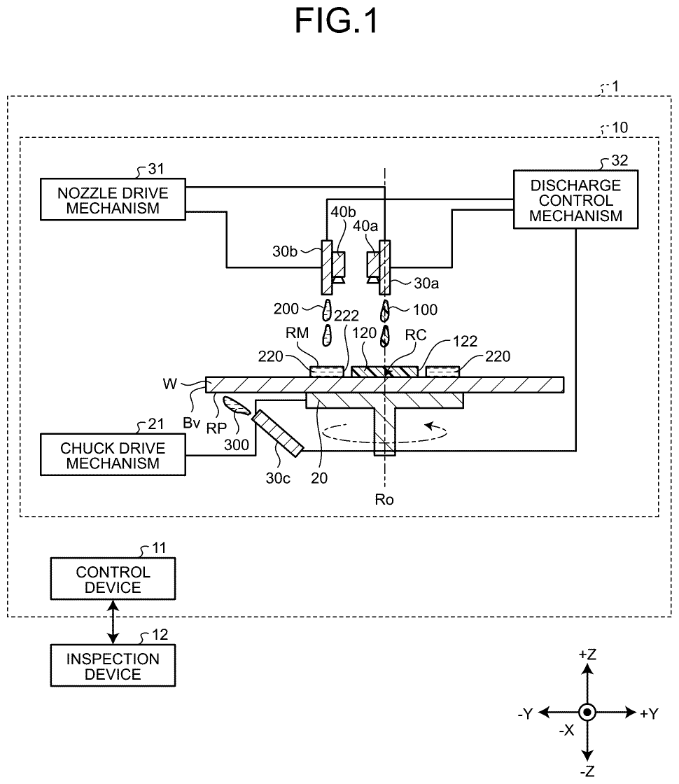

A first embodiment will be described with reference to FIGS. 1 to 8D.

### Configuration Example of Coating Processing Apparatus

FIG. 1 is a cross-sectional view illustrating an example of a state in which a substrate W is placed on a coating processing apparatus 1 according to the first embodiment.

In the present specification, a vertical direction of the coating processing apparatus 1 is a Z direction, an upward direction is a positive direction of Z, and a downward direction is a negative direction of Z. An X direction is a direction along a surface of the substrate W carried into the coating processing apparatus 1. The X direction and the Z direction are directions intersecting each other.

In addition, in the present specification, a direction along the surface of the substrate W carried into the coating processing apparatus 1 and intersecting the X direction and the Z direction is defined as a Y direction. Here, a positive direction of Y and a negative direction of Y are defined so that the negative direction of Y, the positive direction of Z, the positive direction of Y, and the negative direction of Z are arranged clockwise when viewed from a side of a negative direction of X.

As illustrated in FIG. 1, the coating processing apparatus 1 includes a processor 10 and a control device 11. With such configuration, the coating processing apparatus 1 can form a coating film by applying a chemical liquid onto the substrate W.

An inspection device 12 is connected to the control device 11. The inspection device 12 is a defect inspection device capable of inspecting, for example, whether there is a coating defect, as a formation state of the coating film formed on the substrate W. The inspection device 12 transmits an inspection result to the control device 11.

The processor 10 includes a spin chuck 20, a plurality of chemical liquid nozzles 30a to 30c, and cameras 40a and 40b.

The spin chuck 20 is configured to be rotatable while holding the substrate W on which the coating film is to be formed. The spin chuck 20 is formed in a substantially disk shape when viewed from the Z direction. The spin chuck 20 fixes and holds the substrate W on the upper surface thereof by vacuum suction, for example. The spin chuck 20 is an example of a rotary table.

A chuck drive mechanism 21 is connected to the spin chuck 20. The chuck drive mechanism 21 is an actuator including a motor (not illustrated) or the like. The chuck drive mechanism 21 controls a rotating operation and a suction operation of the spin chuck 20 as described above according to an instruction from the control device 11.

Specifically, the chuck drive mechanism 21 rotates the spin chuck 20 around a rotation axis Ro to rotate the substrate W held on the spin chuck 20 at a predetermined number of rotations. As a result, the chemical liquid supplied onto the substrate W is spread toward the outside of the substrate W. In addition, for example, as the number of rotations of the substrate W increases, drying of the substrate W progresses, and the chemical liquid spread on the substrate W may be volatilized. The number of rotations can be controlled by the chuck drive mechanism 21 to be, for example, 1 rpm to 4000 rpm.

Each of the plurality of chemical liquid nozzles 30a to 30c is configured to be able to deliver a predetermined chemical liquid toward the substrate W.

The chemical liquid nozzle 30a is disposed above the substrate W, and is configured to be able to discharge a resist liquid 100 to a first discharge position RC, that is a central portion of the substrate W held on the spin chuck 20, to form a first liquid film 120.

Specifically, the chemical liquid nozzle 30a discharges the resist liquid 100 as a raw material of the first liquid film 120 to the first discharge position RC that is the central portion on the substrate W. The first discharge position RC is a substantially central portion of the substrate W. As a result, the first liquid film 120 is formed in a central region of the substrate W. The chemical liquid nozzle 30a is an example of a first discharge part.

The resist liquid 100 is, for example, a photoresist, and contains an organic solvent such as a thinner as a solvent. The organic solvent contained in the resist liquid 100 discharged onto the substrate W is volatilized by the rotation of the substrate W, whereby a resist layer as a coating film is formed. The viscosity of the resist liquid 100 is, for example, 100 cp or more. The resist liquid 100 is an example of a first coating liquid.

The chemical liquid nozzle 30b is disposed above the substrate W, and is configured to be able to discharge a pre-wet liquid 200 to a second discharge position RM outside the first discharge position RC of the substrate W to form a second liquid film 220.

Specifically, the chemical liquid nozzle 30b discharges the pre-wet liquid 200 as a raw material of the second liquid film 220 to the second discharge position RM outside the substantially central portion on the substrate W. As a result, the second liquid film 220 is formed outside the central region of the substrate W. When the chemical liquid nozzle 30b discharges the pre-wet liquid 200, the chuck drive mechanism 21 rotates the spin chuck 20. As a result, the second liquid film 220 is formed in a substantially annular shape on the substrate W. The pre-wet liquid 200 is an example of a second coating liquid.

The chemical liquid nozzle 30b can also discharge the pre-wet liquid 200 to the first discharge position RC to form a third liquid film (not illustrated). The third liquid film is spread toward the outside of the substrate W by the rotation of the substrate W. As a result, the entire upper surface of the substrate W is covered with the third liquid film. The chemical liquid nozzle 30b is an example of a second discharge part.

The pre-wet liquid 200 is, for example, an organic solvent such as a thinner capable of dissolving the resist liquid 100. Therefore, the pre-wet liquid 200 volatilizes with high-speed rotation of the substrate W. The viscosity of the pre-wet liquid 200 is, for example, 1 to 2 cp.

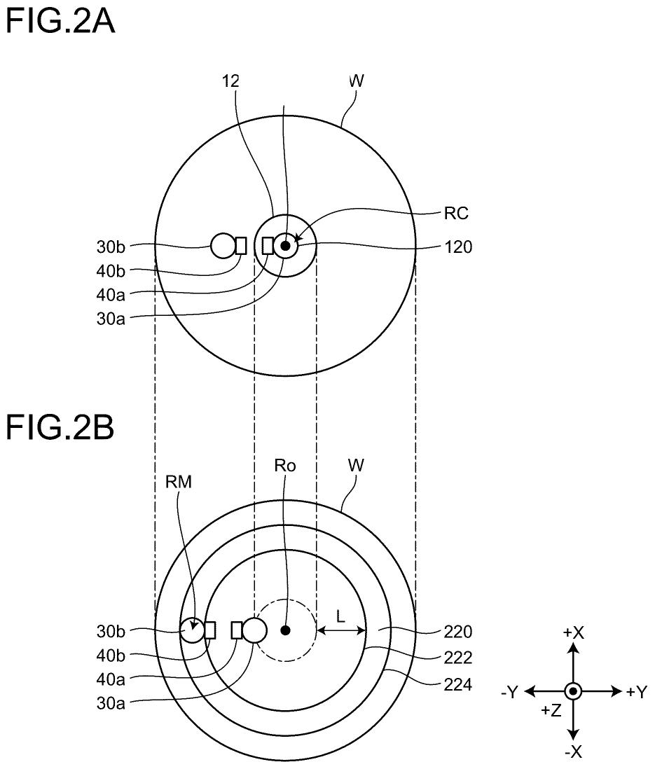

The first liquid film 120 and the second liquid film 220 formed by the coating processing apparatus 1 of FIG. 1 will be described in detail with reference to FIGS. 2A to 2B.

FIGS. 2A to 2B are top views illustrating an example of a state in which the substrate W is placed on the coating processing apparatus 1 according to the first embodiment. For convenience of description, FIGS. 2A to 2B illustrate only the chemical liquid nozzles 30a and 30b, the cameras 40a and 40b, and the substrate W in the configuration of the processor 10.

The substrate W illustrated in FIG. 2A illustrates a state of the first liquid film 120 formed by the chemical liquid nozzle 30a. The first liquid film 120 is formed in a substantially circular shape in the central region of the substrate W when viewed from the Z direction. The first liquid film 120 has an edge 122 as a contour. The edge 122 moves toward the outside of the substrate W around the rotation axis Ro as the substrate W rotates. As the number of rotations of the substrate W increases, a strong centrifugal force acts on the edge 122, so that the edge 122 moves to the outside of the substrate W at a high speed.

A state of the second liquid film 220 formed by the chemical liquid nozzle 30b is illustrated on the substrate W illustrated in FIG. 2B. The second liquid film 220 is formed in a substantially annular shape on the outside of the central region of the substrate W when viewed from the Z direction. The second liquid film 220 has an edge 222 and an edge 224 on the outside of the edge 222 as contours. The edges 222 and 224 move toward the outside of the substrate W around the rotation axis Ro as the substrate W rotates. As the number of rotations of the substrate W increases, a strong centrifugal force acts on each of the edges 222 and 224, so that the edges 222 and 224 move to the outside of the substrate W at a high speed.

As illustrated in FIGS. 2A to 2B, the edge 122 and the edge 222 are concentrically disposed outward about the rotation axis Ro. There is a distance L between the edge 122 and the edge 222.

Returning to FIG. 1, a nozzle drive mechanism 31 is connected to the chemical liquid nozzle 30a and the chemical liquid nozzle 30b. The nozzle drive mechanism 31 is an actuator including a motor (not illustrated) or the like. The nozzle drive mechanism 31 controls driving of the chemical liquid nozzle 30a and the chemical liquid nozzle 30b as described above according to an instruction from the control device 11. As a result, the chemical liquid nozzle 30a and the chemical liquid nozzle 30b can move above the substrate W in the Y direction, for example.

The chemical liquid nozzle 30c is disposed below the substrate W, and is configured to be able to discharge a bevel rinse liquid 300 to a back surface RP and a bevel portion Bv of the substrate W. The bevel rinse liquid 300 is, for example, an organic solvent such as a thinner capable of dissolving the resist liquid 100. The back surface RP and the bevel portion Bv of the substrate W are covered with the bevel rinse liquid 300, so that the portion is cleaned.

The chemical liquid nozzle 30a, the chemical liquid nozzle 30b, and the chemical liquid nozzle 30c are connected to supply pipes (not illustrated), and chemical liquid bottles are connected to the supply pipes, respectively. The supply pipe (not illustrated) is connected to a discharge control mechanism 32. The discharge control mechanism 32 controls discharge of the resist liquid 100, the pre-wet liquid 200, and the bevel rinse liquid 300 as described above according to an instruction from the control device 11. As a result, the chemical liquid nozzle 30a, the chemical liquid nozzle 30b, and the chemical liquid nozzle 30c can discharge the chemical liquids at freely selected timings and at freely selected flow rates, respectively.

The camera 40a and the camera 40b are imaging sensors capable of imaging an imaging target at a speed of 1 to several tens of fps, for example. The camera 40a and the camera 40b are provided in each of the chemical liquid nozzle 30a and the chemical liquid nozzle 30b.

Specifically, the camera 40a is installed on the side surface of the chemical liquid nozzle 30a to face the negative direction of Z. The camera 40a captures an image of the edge 122 of the first liquid film 120 spreading toward the outside of the substrate W. In addition, the camera 40b is installed on the side surface of the chemical liquid nozzle 30b to face the negative direction of Z. The camera 40b captures an image of the edge 222 of the second liquid film 220 spreading toward the outside of the substrate W. When imaging the edge 122 and the edge 222, the nozzle drive mechanism 31 appropriately controls driving of the chemical liquid nozzle 30a and the chemical liquid nozzle 30b in the Y direction. The camera 40a is an example of a first imaging device. Furthermore, the camera 40b is an example of a second imaging device.

The camera 40a and the camera 40b capture images of the edge 122 and the edge 222 at predetermined time intervals from the start to the end of discharge of the resist liquid 100 by the chemical liquid nozzle 30a, and transmit imaging results to the control device 11.

### Configuration Example of Control Device

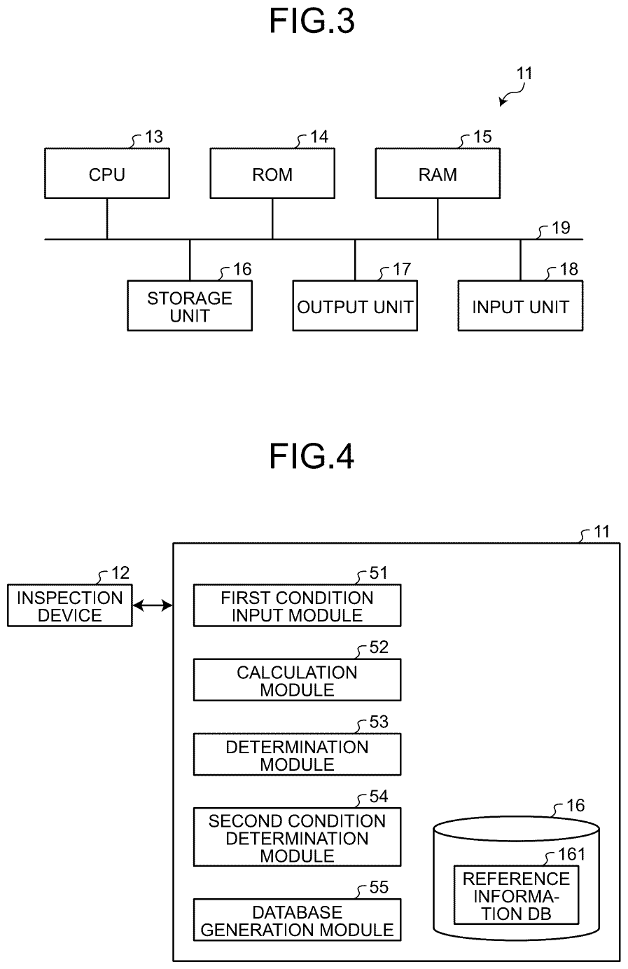

Next, a configuration example of the control device 11 will be described with reference to FIGS. 3 and 4.

FIG. 3 is a block diagram illustrating an example of a hardware configuration of the control device 11 according to the first embodiment. The control device 11 exemplified here includes a microcomputer (processor) to which a central processing unit (CPU) 13, a read only memory (ROM) 14, a random access memory (RAM) 15, a storage unit 16, an output unit 17, an input unit 18, and the like are connected via a bus 19. The CPU 13 executes the coating film forming process according to a program stored in the ROM 14, the storage unit 16, and the like. The RAM 15 is used as a work area or the like of the CPU 13. The output unit 17 can be, for example, a display or the like. The input unit 18 can be, for example, a keyboard, a touch panel mechanism, a pointing device, or the like.

The control device 11 controls each unit of the processor 10 related to the coating film forming process based on a program stored in the storage unit 16 or the like and a recipe to be loaded. Here, the control device 11 refers to the imaging results acquired from the cameras 40a and 40b, the inspection result acquired from the inspection device 12, and the like.

FIG. 4 is a block diagram illustrating an example of a functional configuration of the control device 11 according to the first embodiment; As illustrated in FIG. 4, the control device 11 functions as a first condition input module 51, a calculation module 52, a determination module 53, a second condition determination module 54, a database generation module 55, and the storage unit 16 as functional units for executing the coating film forming process.

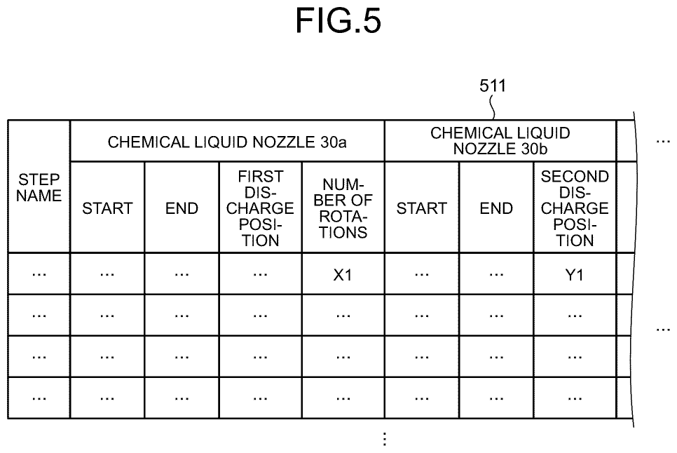

First, a recipe that is an input target of a first condition will be described with reference to FIG. 5. FIG. 5 is a diagram illustrating an example of a recipe table 511 included in the control device 11 according to the first embodiment.

The first condition is a condition for starting a process of forming the first liquid film 120 and the second liquid film 220. Specifically, the first condition is a parameter about a timing when the formation of the first liquid film 120 and the second liquid film 220 is started. As the first condition, for example, information related to the number of rotations of the substrate W and the position of the second discharge position RM is applicable, but the first condition is not limited thereto.

As illustrated in FIG. 5, a plurality of recipes are recorded in the recipe table 511. Various parameters for performing the coating film forming process on the substrate W are set in each recipe. Specifically, for example, in the recipe, a plurality of parameters related to the chemical liquid nozzle and the like are set in addition to a step name. Such a recipe table 511 is presented to the user in the output unit 17, for example. The user selects a desired recipe from the recipe table 511.

“Step name” is an item for which a name for identifying a step is set. The step is distinguished by a combination of, for example, the type of the substrate W, the type of the resist liquid 100 to be discharged, and the type of the pre-wet liquid 200. Therefore, for example, when the combinations of the substrate W, the resist liquid 100, and the pre-wet liquid 200 are the same, the same name can be set as the same step.

Examples of the parameter related to “chemical liquid nozzle 30a” include a discharge start timing (“start” in the drawing), a discharge end timing (“end” in the drawing), a discharge position (“first discharge position” in the drawing), and a number of rotations (“number of rotations” in the drawing).

“Discharge start timing” is a timing at which the chemical liquid nozzle 30a starts to discharge the resist liquid 100 to the first discharge position RC. “Discharge end timing” is a timing at which the chemical liquid nozzle 30a ends the discharge of the resist liquid 100. “First discharge position” is information related to the position of the first discharge position RC. “Number of rotations” is the number of rotations of the substrate W when the chemical liquid nozzle 30a starts discharging the resist liquid 100. The number of rotations is an example of a rotation speed.

The parameters related to “chemical liquid nozzle 30b” include a discharge start timing (“start” in the drawing), a discharge end timing (“end” in the drawing), a discharge position (“second discharge position” in the drawing), and the like.

“Discharge start timing” is a timing at which the chemical liquid nozzle 30b starts to discharge the pre-wet liquid 200 to the second discharge position RM. “Discharge end timing” is a timing at which the chemical liquid nozzle 30b ends the discharge of the pre-wet liquid 200. “Second discharge position” is information related to the position of the second discharge position RM.

The first condition input module 51 receives an input of the first condition with such a recipe as an input target.

Specifically, the first condition input module 51 receives an input of “X1” as the first condition in “number of rotations” among the parameters related to “chemical liquid nozzle 30a”, for example. As a result, the number of rotations of the substrate W at the timing when the discharge of the resist liquid 100 from the chemical liquid nozzle 30a is started is set to “X1”.

The first condition input module 51 also receives an input of “Y1” as the first condition at “second discharge position” among the parameters related to “chemical liquid nozzle 30b”, for example. As a result, the second discharge position RM at the timing when the discharge of the pre-wet liquid 200 is started is set to “Y1”.

Such a first condition is freely determined by the user. The user performs an operation of inputting the first condition via the input unit 18, for example. When inputting the first condition, the user may refer to, for example, a reference information DB 161 to be described later.

Upon receiving the input of the first condition, the first condition input module 51 loads the recipe. As a result, the coating film forming process using the parameters registered in the recipe is started.

Returning to FIG. 4, the calculation module 52 calculates the distance L between the edge 122 of the first liquid film 120 and the edge 222 of the second liquid film 220 based on captured images acquired from the cameras 40a and 40b.

Specifically, for example, the calculation module 52 specifies the position of the edge 122 at a predetermined time t based on the captured image acquired from the camera 40a. The position of the edge 122 is specified with respect to the position of the chemical liquid nozzle 30a when the captured image is acquired. Further, the calculation module 52 specifies the position of the edge 222 at the predetermined time t based on the captured image acquired from the camera 40b. The position of the edge 222 is specified with respect to the position of the chemical liquid nozzle 30b when the captured image is acquired. As such, the calculation module 52 calculates the distance L between the edge 122 and the edge 222 at the predetermined time t.

The calculation module 52 executes the process of calculating the distance L at predetermined time intervals from the start to the end of the discharge of the resist liquid 100. In addition, the calculation module 52 calculates the speed at which each of the edge 122 and the edge 222 spreads on the substrate W as an analysis result based on the positions of the edge 122 and the edge 222 at predetermined time intervals.

The determination module 53 determines whether the distance L calculated by the calculation module 52 exceeds a predetermined range. The predetermined range used for the determination by the determination module 53 is, for example, equal to or more than a distance at which the edge 122 and the edge 222 are not in contact with each other and equal to or less than 4 cm. More preferably, the thickness is several mm or more and 4 cm or less. That is, the determination module 53 determines that the distance L exceeds the predetermined range when the edge 122 and the edge 222 are in contact with each other or when the distance L between the edge 122 and the edge 222 exceeds 4 cm.

The second condition determination module 54 controls the number of rotations of the substrate W so that the distance L falls within a predetermined range based on the imaging results acquired from the camera 40a and the camera 40b. Specifically, when the determination module 53 determines that the distance L falls within the predetermined range, the second condition determination module 54 controls the number of rotations of the substrate W so that the distance L is maintained within the predetermined range based on the analysis result of the calculation module 52.

For example, the second condition determination module 54 specifies transition of the distance L between time t1 and time t2 after starting to discharge the resist liquid 100. For example, when the distance L decreases from the time t1 to the time t2, the second condition determination module 54 determines the number of rotations of the substrate W after the time t2 and until the discharge of the resist liquid 100 is ended as “X2” as a second condition smaller than “X1” received as the first condition.

The second condition is a condition for maintaining the distance L within a predetermined range. Specifically, the second condition is a parameter determined to maintain the distance L within a predetermined range after the first liquid film 120 and the second liquid film 220 are formed. As the second condition, for example, information related to the number of rotations of the substrate W and the position of the second discharge position RM is applicable, but the second condition is not limited thereto.

The second condition determination module 54 controls the chuck drive mechanism 21 so that the number of rotations of the substrate W becomes “X2” that is the second condition. As a result, since the number of rotations of the substrate W decreases, the speed at which the edge 122 and the edge 222 spread on the substrate W decreases. As a result, the decrease in the distance L is suppressed, and the distance L between the edge 122 and the edge 222 can be maintained within a predetermined range. “The distance L is maintained within the predetermined range” includes not only a case where the distance L falls within the predetermined range but also a case where the distance L is maintained with a slight error from the predetermined range.

On the other hand, for example, when the distance L increases from the time t1 to the time t2, the second condition determination module 54 determines the number of rotations of the substrate W after the time t2 and until the discharge of the resist liquid 100 is ended as “X3” as a second condition larger than “X1” received as the first condition.

The second condition determination module 54 controls the chuck drive mechanism 21 so that the number of rotations of the substrate W becomes “X3” that is the second condition. As a result, since the number of rotations of the substrate W increases, the speed at which the edge 122 and the edge 222 spread on the substrate W increases. As a result, the increase in the distance L is suppressed, and the distance L between the edge 122 and the edge 222 can be maintained within a predetermined range.

In addition, the second condition determination module 54 determines not to control the number of rotations of the substrate W described above when the distance L exceeds the predetermined range.

Specifically, when the determination module 53 determines that the distance L exceeds the predetermined range, the second condition determination module 54 controls the chuck drive mechanism 21, the nozzle drive mechanism 31, the discharge control mechanism 32, and the like to execute processing of stopping the coating film forming process of the substrate W. As a result, the coating film forming process of the substrate W is stopped, and the substrate W is carried out from the processor 10. The second condition determination module 54 is an example of a controller.

Here, the reason why the second condition determination module 54 determines to stop the process when it is determined that the distance L exceeds the predetermined range will be described.

As described above, the predetermined range of the distance L is equal to or more than a distance at which the edge 122 and the edge 222 are not in contact with each other and equal to or less than 4 cm. For example, when the edge 122 and the edge 222 come into contact with each other before the discharge of the resist liquid 100 is ended, the contour of the edge 122 formed in a substantially circular shape may be deformed. When the first liquid film 120 of which the contour is deformed is applied and spread on the substrate W, the centrifugal force is not uniformly applied to the edge 122, and the first liquid film 120 unevenly spreads on the substrate W. As a result, the possibility of occurrence of coating failure increases.

On the other hand, for example, if the distance L exceeds 4 cm before the discharge of the resist liquid 100 is ended, the second liquid film 220 covering the outside of the central region of the substrate W may volatilize before the first liquid film 120 is spread on the outer peripheral portion of the substrate W. As a result, fluidity of the resist liquid 100 in the outer peripheral portion of the substrate W is not sufficiently improved, and the possibility of occurrence of coating failure increases. As a result, the flow rate of the resist liquid 100 is increased, and the effect of chemical liquid may not be obtained.

As described above, it is determined that the coating failure is highly likely to occur when the distance L exceeds the predetermined range, and the process of the substrate W is immediately stopped, whereby the subsequent processes can be omitted. As a result, the processing cost can be reduced.

For the substrate W on which the coating film is formed, the database generation module 55 generates a reference information database (hereinafter, referred to as reference information DB) 161 in which the number of rotations of the substrate W determined as the second condition, the second discharge position RM, the distance L calculated as the analysis result, the speed at which the first liquid film 120 and the second liquid film 220 spread on the substrate W, and the inspection result obtained by inspecting the formation state of the coating film are associated with each other, and stores the reference information DB in the storage unit 16. The reference information DB 161 is an example of reference information.

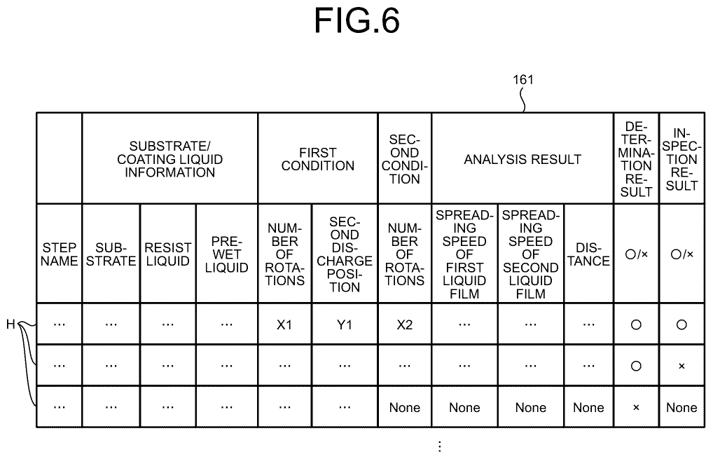

FIG. 6 is a diagram illustrating an example of the reference information DB 161 stored in the storage unit 16 according to the first embodiment.

As illustrated in FIG. 6, a plurality of processing histories H are recorded in the reference information DB 161. In each processing history H, “substrate/chemical liquid information”, “first condition”, “second condition”, “analysis result”, and “inspection result” are associated with each “step name”.

“Step name” is, for example, a name for identifying a step as described above. In “step name” in the example of FIG. 6, a name corresponding to “step name” set in the recipe loaded in the first condition input module 51 is recorded.

As items related to “substrate/coating liquid information”, the type of the substrate W, the type of the resist liquid 100, the type of the pre-wet liquid 200, and the like are recorded. “Substrate/coating liquid information” is information associated in advance with “step name” set in the recipe. Furthermore, “substrate/chemical liquid information” may include, for example, information regarding the viscosity, boiling point, and the like of the resist liquid 100 and the pre-wet liquid 200 in addition to the items illustrated in FIG. 6.

As an item related to “first condition”, the first condition received by the first condition input module 51 is recorded. In the example of FIG. 6, information is recorded that is input as “first condition” regarding the number of rotations of the substrate W and the position of the second discharge position RM when the discharge of the resist liquid 100 is started. Here, for example, “X1” is recorded as “number of rotations”. Furthermore, for example, “Y1” is recorded as “second discharge position”.

As an item related to “second condition”, the second condition determined by the second condition determination module 54 is recorded. That is, in “second condition”, the number of rotations of the substrate W determined by the second condition determination module 54 and subjected to control is recorded. In the example of FIG. 6, for example, “X2” is recorded as “second condition”. In addition, when the second condition determination module 54 determines not to control the number of rotations, the coating film forming process of the substrate W is stopped, and thus “None” meaning that there is no record of the second condition is recorded.

As an item related to “analysis result”, an analysis result in the calculation module 52 is recorded. In the example of FIG. 6, a spreading speed on the substrate W and the distance L at a predetermined time of each of the first liquid film 120 and the second liquid film 220 when the substrate W is rotated at the number of rotations “X2” as the second condition are recorded. When the second condition determination module 54 determines not to control the number of rotations, “None” is recorded.

As an item related to “determination result”, the determination result determined by the determination module 53 is recorded in the form of “O/X”. In the example of FIG. 6, the determination result at the predetermined time when the substrate W is rotated at the number of rotations “X2” as the second condition is recorded. The predetermined time is, for example, when the discharge of the resist liquid 100 is ended. That is, for example, in “determination result”, when the distance L at the end of the discharge of the resist liquid 100 does not exceed the predetermined range, the item is indicated by “O”, and when the distance L exceeds the predetermined range, the item is indicated by “X”.

As the item related to “inspection result”, the inspection result of the substrate W in the inspection device 12 is recorded in the form of “O/X”. For example, as a result of inspecting the formation state of the coating film, when no coating defect is found on the substrate W, the item is indicated by “O”, and when a coating defect is found on the substrate W, the item is indicated by “X”. When the second condition determination module 54 determines not to control the number of rotations, “None” is recorded because the inspection of the substrate W is not performed.

The storage unit 16 is a storage medium such as an HDD or a solid state drive (SSD). The storage unit 16 stores a recipe table 511, the above-described reference information DB 161 including an analysis result, a determination result, and an inspection result, and the like.

### Method for Forming Coating Film

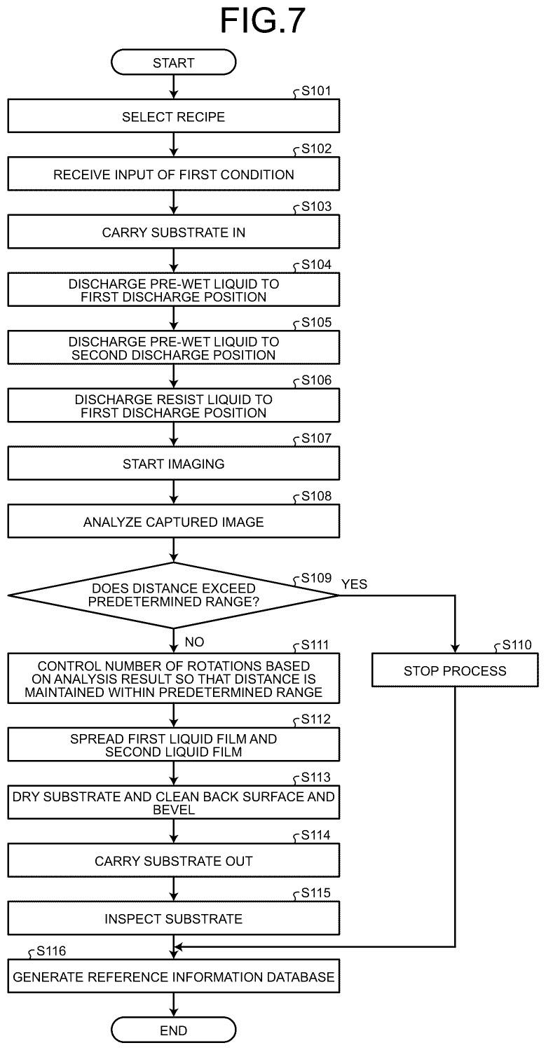

A method for forming a coating film of the first embodiment will be described with reference to FIG. 7. FIG. 7 is a flowchart for explaining a flow of a coating film forming process according to the first embodiment.

When a desired recipe is selected by the user (S101), the first condition input module 51 receives an input of the first condition (S102).

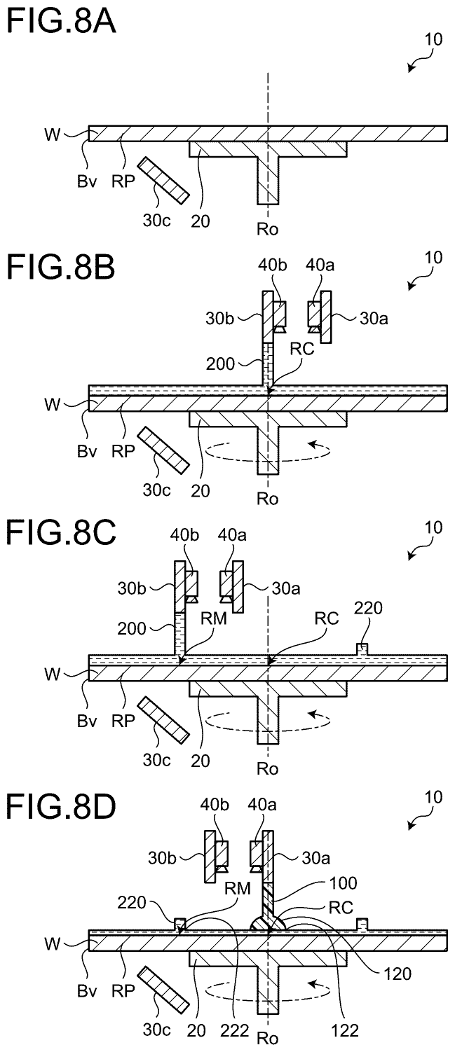

The processing in the processor 10 is started by accepting the input of the first condition and loading the recipe. Hereinafter, processes in steps S103 to S106 in FIG. 7 will be described with reference to FIGS. 8A to 8D.

FIGS. 8A to 8D are diagrams for explaining a flow of the process in the processor 10 of the first embodiment. FIGS. 8A to 8D are cross-sectional views illustrating a state in which the substrate W is placed on the coating processing apparatus 1. Note that, for convenience of description, only a part of the configuration of the processor 10 illustrated in FIG. 1 is illustrated in FIGS. 8A to 8D.

When the recipe is loaded, as illustrated in FIG. 8A, the substrate W is carried into the processor 10 and held on the spin chuck 20 (S103).

Next, as illustrated in FIG. 8B, when the nozzle drive mechanism 31 moves the chemical liquid nozzle 30b to above the first discharge position RC, the discharge control mechanism 32 causes the chemical liquid nozzle 30b to discharge the pre-wet liquid 200 (S104).

Here, the chuck drive mechanism 21 rotates the spin chuck 20 at a predetermined number of rotations to rotate the substrate W. As a result, the pre-wet liquid 200 is spread on the substrate W, and the upper surface of the substrate W is covered with the pre-wet liquid 200.

Next, as illustrated in FIG. 8C, when the nozzle drive mechanism 31 moves the chemical liquid nozzle 30b to above the second discharge position RM, the discharge control mechanism 32 causes the chemical liquid nozzle 30b to discharge the pre-wet liquid 200 (S105).

Here, the chuck drive mechanism 21 rotates the substrate W at a predetermined number of rotations. As described with reference to FIG. 2B, the predetermined number of rotations is preferably such a number of rotations that the pre-wet liquid 200 goes around the substrate W once and the substantially annular second liquid film 220 is formed. The second liquid film 220 formed on the substrate W starts to spread outward as the substrate W rotates. As such, the pre-wet liquid 200 is replenished to the outer peripheral portion of the substrate W.

Next, as illustrated in FIG. 8D, when the nozzle drive mechanism 31 moves the chemical liquid nozzle 30a to above the first discharge position RC, the discharge control mechanism 32 causes the chemical liquid nozzle 30a to discharge the resist liquid 100 (S106).

Here, the chuck drive mechanism 21 rotates the substrate W at the number of rotations based on the first condition together with the start of discharge of the resist liquid 100 by the chemical liquid nozzle 30a. The first liquid film 120 formed at the first discharge position RC starts to spread outward as the substrate W rotates.

Returning to FIG. 7, the description of step S107 and subsequent steps will be continued.

The camera 40a and the camera 40b start imaging the edge 122 of the first liquid film 120 and the edge 222 of the second liquid film 220 simultaneously with the start of the discharge of the resist liquid 100 (S107). The camera 40a and the camera 40b transmit captured images at predetermined time intervals to the calculation module 52.

The calculation module 52 analyzes the acquired captured image (S108). Specifically, the calculation module 52 calculates the distance L between the edge 122 and the edge 222 as an analysis result. In addition, the calculation module 52 calculates the speed at which the edge 122 and the edge 222 spread on the substrate W as an analysis result.

The determination module 53 determines whether the distance L exceeds the predetermined range at predetermined time intervals (S109).

When the determination module 53 determines that the distance L exceeds the predetermined range (S109→Yes), the second condition determination module 54 stops the coating film forming process of the substrate W (S110).

When the determination module 53 determines that the distance L does not exceed the predetermined range (S109→No), the second condition determination module 54 controls the number of rotations of the substrate W so that the distance L is maintained within the predetermined range based on the captured images by the camera 40a and the camera 40b (S111).

Specifically, for example, the second condition determination module 54 changes the number of rotations of the substrate W in the remaining time until the discharge of the resist liquid 100 is ended to the second condition different from the first condition based on the transition of the distance L for each time.

When the discharge of the resist liquid 100 is ended, the chuck drive mechanism 21 rotates the substrate W at a high number of rotations different from the second condition, and spreads the first liquid film 120 and the second liquid film 220 to the outside of the substrate W at once (S112).

Next, the chuck drive mechanism 21 further rotates the substrate W at a high number of rotations to volatilize an organic solvent contained in the first liquid film 120 and the second liquid film 220. As a result, a resist layer as a coating film is formed on the substrate W.

Next, when the rotation of the substrate W is continued, the discharge control mechanism 32 causes the chemical liquid nozzle 30c to discharge the pre-wet liquid 200 to the back surface RP and the bevel portion Bv of the substrate W. As a result, the back surface RP and the bevel portion Bv of the substrate W are cleaned (S113).

Next, the chuck drive mechanism 21 releases the holding of the substrate W. As a result, the substrate W can be carried out from the processor 10 (S114).

Next, the substrate W is conveyed to the inspection device 12 (not illustrated). When the inspection of the substrate W is completed (S115), the inspection device 12 transmits the inspection result to the database generation module 55.

The database generation module 55 generates the reference information DB 161 in which the first condition, the second condition, the analysis result, and the inspection result are recorded in association with each other (S116).

The coating film forming process of the first embodiment is thus completed.

### Comparative Example

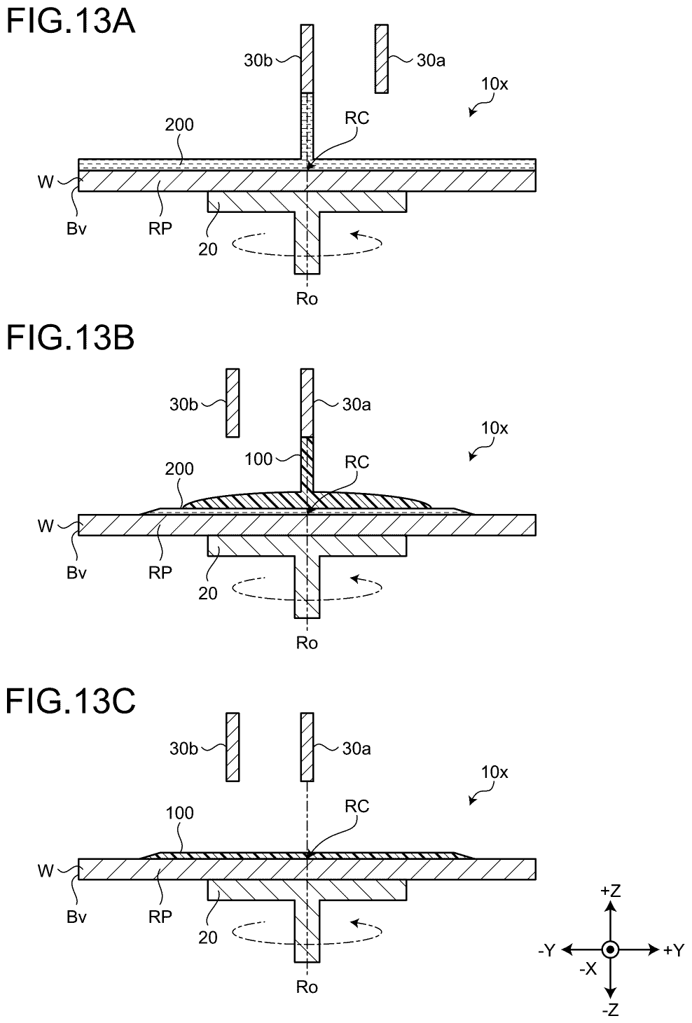

FIGS. 13A to 13C are diagrams for explaining a flow of a coating film forming process in a processor 10x of a comparative example. FIGS. 13A to 13C are cross-sectional views illustrating a state in which the substrate W is placed on the processor 10x of the comparative example.

As illustrated in FIG. 13A, in the processor 10x of the comparative example, the pre-wet liquid 200 is discharged to the first discharge position RC while the substrate W rotates, and is spread toward the outside of the substrate W. Next, as illustrated in FIG. 13B, the resist liquid 100 is discharged to the first discharge position RC. Next, as illustrated in FIG. 13C, the resist liquid 100 is spread outward with the rotation of the substrate W.

Here, immediately before discharge of the resist liquid 100 illustrated in FIG. 13B, the pre-wet liquid 200 spread on the substrate W may volatilize at the outer peripheral portion of the substrate W. As a result, the fluidity of the resist liquid 100 in the outer peripheral portion of the substrate W may not be sufficiently improved. As a result, as illustrated in FIG. 13C, the resist liquid 100 does not sufficiently spread to the outer peripheral portion of the substrate W, and coating failure or the like may occur in the outer peripheral portion of the substrate W.

### Overview

The coating processing apparatus 1 of the first embodiment images the edge 122 of the first liquid film 120 by the resist liquid 100 discharged to the first discharge position RC that is the central portion of the substrate W, and the edge 222 of the second liquid film 220 by the pre-wet liquid 200 discharged to the second discharge position RM outside the first discharge position RC. The control device 11 controls the number of rotations of the substrate W based on the imaging result so that the distance L between the edge 122 and the edge 222 falls within a predetermined range.

As described above, since the pre-wet liquid 200 is replenished to the second discharge position RM outside the first discharge position RC, the fluidity of the resist liquid 100 at the outer peripheral portion of the substrate W is improved, and the resist liquid 100 can be sufficiently spread to the outer periphery with a small discharge amount. Here, the number of rotations of the substrate W is controlled so that the distance L between the first liquid film 120 and the second liquid film 220 maintains a predetermined distance. Accordingly, it is possible to suppress coating failure of the substrate W while reducing the consumption of the resist liquid 100.

The coating processing apparatus 1 of the first embodiment controls the number of rotations of the substrate W so that the distance L is maintained within a predetermined range when the distance L is within the predetermined range. In addition, the control device 11 does not control the number of rotations of the substrate W when the distance L exceeds the predetermined range.

As such, since the possibility of the coating failure can be predicted by determining whether the distance L falls within the predetermined range based on the imaging result, it is possible to avoid performing unnecessary process on the substrate W having a high possibility of coating failure or the like. As a result, the processing cost can be reduced.

### Modification

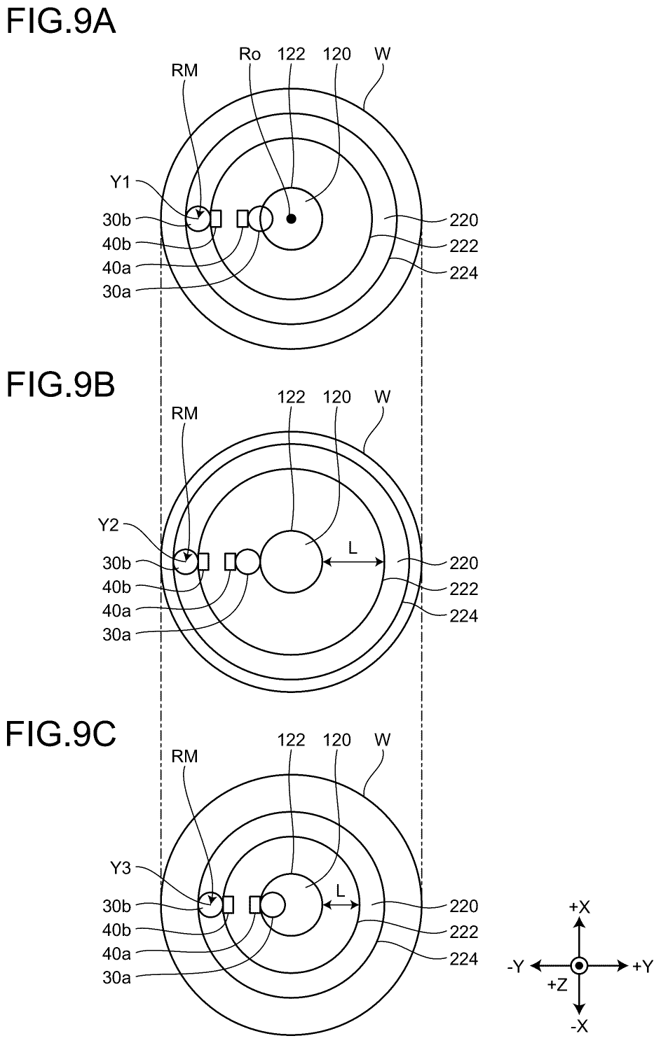

A modification of the first embodiment will be described with reference to FIGS. 9A to 9C.

A coating processing apparatus and a coating processing method of the modification are different from those of the first embodiment in that the second discharge position RM is determined instead of the control of the number of rotations of the substrate W. In the following description, the same reference numerals are given to the same configurations as those of the first embodiment described above, and the description thereof may be omitted.

FIGS. 9A to 9C are top views illustrating an example of a state in which the substrate W is placed on the coating processing apparatus 1 according to the modification of the first embodiment. For convenience of description, FIGS. 9A to 9C illustrate only the chemical liquid nozzles 30a and 30b, the cameras 40a and 40b, and the substrate W in the configuration of the processor 10.

The first liquid film 120 formed by the chemical liquid nozzle 30a and the second liquid film 220 formed by the chemical liquid nozzle 30b are illustrated on the substrate W illustrated in FIGS. 9A to 9C.

FIG. 9A illustrates a formation position of the second liquid film 220 when the second discharge position RM is set to “Y1” as the first condition in the first condition input module 51.

When the determination module 53 determines that the distance L between the edge 122 and the edge 222 falls within the predetermined range, the second condition determination module 54 determines the second discharge position RM so that the distance L is maintained within the predetermined range based on the analysis result of the calculation module 52.

For example, the second condition determination module 54 specifies transition of the distance L between time t1 and time t2 after starting to discharge the resist liquid 100. For example, when the distance L decreases from the time t1 to the time t2, the second condition determination module 54 determines the position of the second discharge position RM as “Y2” illustrated in FIG. 9B as the second condition. “Y2” is a position on a side of the negative direction of Y from “Y1” received as the first condition, that is, on the outer side of the substrate W as viewed from the rotation axis Ro.

The second discharge position RM as the second condition determined as such is applied to, for example, second and subsequent substrates W when a plurality of substrates W is processed with the same recipe. For example, the second condition determination module 54 controls the nozzle drive mechanism 31 so that the second discharge position RM becomes “Y2” in the second and subsequent substrates W. As a result, since the position of the second discharge position RM is set on the outer side of the substrate W in advance, the distance L between the edge 122 and the edge 222 can be secured widely in advance. As a result, the distance L between the edge 122 and the edge 222 can be maintained within a predetermined range until the discharge of the resist liquid 100 is ended.

On the other hand, for example, when the distance L increases from the time t1 to the time t2, the second condition determination module 54 determines the position of the second discharge position RM as “Y3” illustrated in FIG. 9C as the second condition. “Y3” is a position on a side of the positive direction of Y from “Y1” received as the first condition, that is, on the inner side of the substrate W as viewed from the rotation axis Ro.

For example, the second condition determination module 54 controls the nozzle drive mechanism 31 so that the second discharge position RM becomes “Y3” in the second and subsequent substrates W. As a result, since the position of the second discharge position RM is set on the inner side of the substrate W in advance, the distance L between the edge 122 and the edge 222 can be narrowed in advance. As a result, the distance L can be maintained within a predetermined range until the discharge of the resist liquid 100 is ended.

According to the coating processing apparatus and the coating processing method of the modification, the same effects as those of the coating processing apparatus and the coating processing method of the first embodiment are obtained.

### Second Embodiment

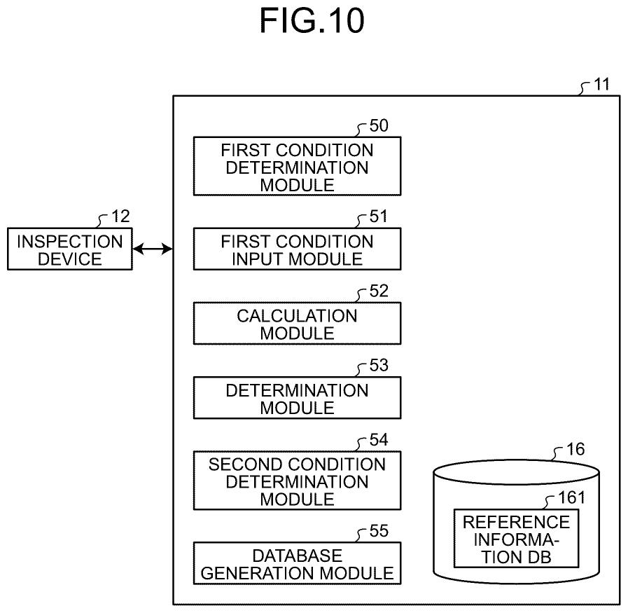

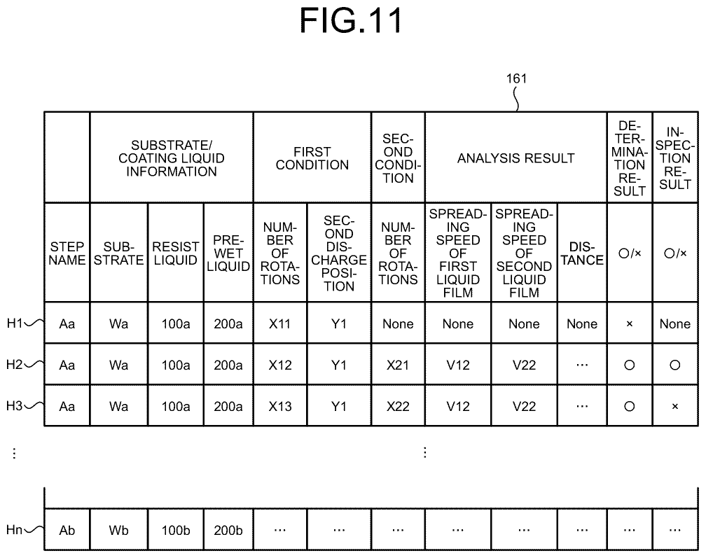

A second embodiment will be described with reference to FIGS. 10 and 11. The coating processing apparatus and the method for forming a coating film of the second embodiment are different from those of the first embodiment described above in that the first condition is determined based on the generated reference information DB 161. In the following description, the same reference numerals are given to the same configurations as those of the first embodiment described above, and the description thereof may be omitted.

### Configuration Example of Coating Processing Apparatus

FIG. 10 is a block diagram illustrating an example of a functional configuration of the control device 11 according to the second embodiment.

As illustrated in FIG. 10, the control device 11 functions as a first condition determination module 50, the first condition input module 51, the calculation module 52, the determination module 53, the second condition determination module 54, the database generation module 55, and the storage unit 16 as functional units for executing the coating process.

Based on the reference information DB 161, the first condition determination module 50 determines the number of rotations of the substrate W and the second discharge position RM when the formation state of the coating film satisfies the predetermined condition as the first conditions for starting the formation of the first liquid film 120 and the second liquid film 220. The predetermined condition used for the determination by the first condition determination module 50 is a condition that “inspection result” in the reference information DB 161 indicates “O”. The first condition is an example of a condition.

A method for determining the first condition in the first condition determination module 50 will be described in detail with reference to FIG. 11. FIG. 11 is a diagram illustrating an example of the reference information DB 161 stored in the storage unit 16 according to the second embodiment.

As illustrated in FIG. 11, the reference information DB 161 records processing histories H1 to Hn. In each of the processing histories H1 to Hn, “substrate/chemical liquid information”, “first condition”, “second condition”, “analysis result”, and “inspection result” are recorded in association with each “step name”. Note that, when it is not necessary to individually distinguish the processing histories H1 to Hn, the processing histories H1 to Hn may be hereinafter referred to as “processing history H”. The reference information DB 161 is an example of reference information.

In the example of FIG. 11, the same “step name” is recorded in each of the processing histories H1 to H3. That is, in each of the processing histories H1 to H3, an analysis result and an inspection result when the coating film forming process is executed under different conditions in the same step “Aa” are recorded.

The first condition determination module 50 specifies the processing history H2 in which “inspection result” indicates “O” as a condition satisfying a predetermined condition among the processing histories H1 to H3 processed in the same step “Aa”. Then, the first condition determination module 50 determines the first condition based on the processing history H2.

For example, the first condition determination module 50 determines, as the first condition, “Y1” that is “second discharge position” recorded in “first condition” and “X21” that is “number of rotations” recorded in “second condition” in the processing history H2. The first condition determination module 50 transmits the determined first condition to the first condition input module 51. The first condition determination module 50 is an example of a controller.

The first condition input module 51 receives an input of the first condition from the first condition determination module 50. Specifically, the first condition input module 51 receives an input of the first condition associated with “step name” corresponding to “step name” of the recipe selected by the user. Upon receiving the input of the first condition, the first condition input module 51 loads the recipe. Accordingly, the coating film forming process is executed under the first condition.

When the determination module 53 determines that the distance L falls within the predetermined range, the second condition determination module 54 controls the number of rotations of the substrate W so that the distance L falls within the predetermined range based on the reference information DB 161 and the imaging result obtained by imaging the edge 122 of the first liquid film 120 and the edge 222 of the second liquid film 220 formed using the first condition. Specifically, the second condition determination module 54 controls the number of rotations of the substrate W so that the distance L is maintained within a predetermined range based on the speed at which the first liquid film 120 and the second liquid film 220 spread on the substrate W included in the reference information DB 161 and the analysis result in the calculation module 52.

For example, the second condition determination module 54 specifies the transition of the distance L between the time t1 and the time t2 after starting to discharge the resist liquid 100 based on the analysis result. For example, when the distance L decreases from the time t1 to the time t2, the second condition determination module 54 determines the number of rotations of the substrate W after the time t2 and until the discharge of the resist liquid 100 is ended as the second condition smaller than “X21” as the first condition received by the first condition input module 51 based on “number of rotations” as the second condition, “spreading speed of first liquid film”, and “spreading speed of second liquid film” recorded in the processing histories H1 to H3.

On the other hand, for example, when the distance L increases from the time t1 to the time t2, the second condition determination module 54 determines the number of rotations of the substrate W during the time after the time t2 before the discharge of the resist liquid 100 is ended as the second condition larger than “X21” received by the first condition input module 51 based on “number of rotations” as the second condition, “spreading speed of first liquid film”, and “spreading speed of second liquid film” recorded in the processing histories H1 to H3.

The second condition determination module 54 controls the chuck drive mechanism 21 so that the number of rotations of the substrate W becomes the number of rotations determined by the second condition. As a result, the number of rotations of the substrate W is adjusted, and the speed at which each of the edge 122 of the first liquid film 120 and the edge 222 of the second liquid film 220 spreads on the substrate W is adjusted. As a result, the distance L between the edge 122 and the edge 222 can be maintained within a predetermined range.

### Method for Forming Coating Film

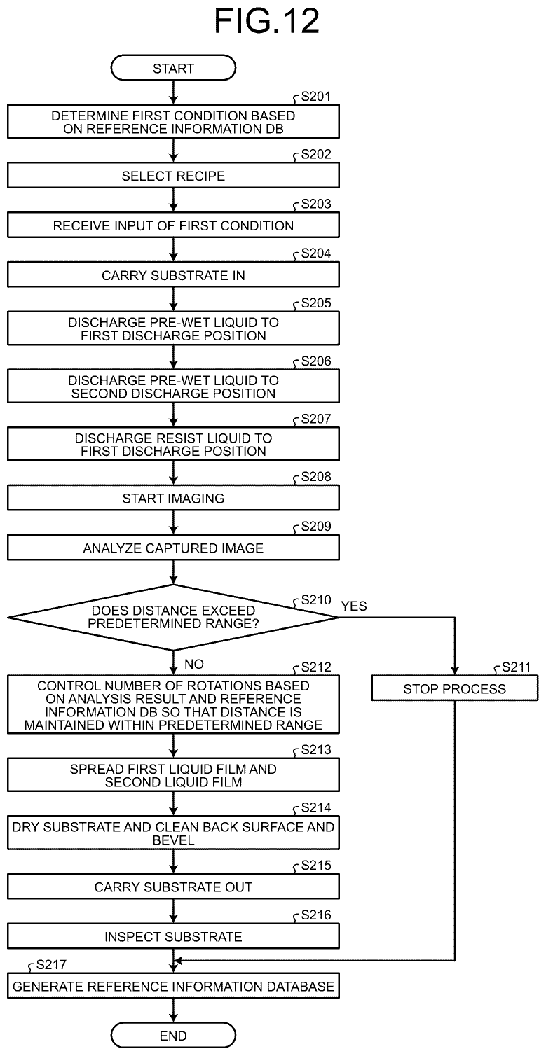

A method for forming a coating film of the second embodiment will be described with reference to FIG. 12. FIG. 12 is a flowchart for explaining a flow of a coating film forming process according to the second embodiment.

Based on the reference information DB 161, the first condition determination module 50 determines the number of rotations of the substrate W and the second discharge position RM when the “determination result” indicates “O” as the first conditions (S201).

When a desired recipe is selected by the user (S202), the first condition input module 51 receives an input of the first condition from the first condition determination module 50 (S203).

Note that the process in steps S204 to S211 and the process in steps S213 to S217 are similar to the process in steps S103 to S110 and the process in steps S112 to S116 in FIG. 7, respectively, and thus description thereof is omitted.

When the determination module 53 determines that the distance L does not exceed the predetermined range (S210→No), the second condition determination module 54 controls the number of rotations of the substrate W so that the distance L is maintained within the predetermined range based on the analysis result in the calculation module 52 and the reference information DB 161 (S212).

The coating film forming process of the second embodiment is completed as described above.

As such, the first condition having a low possibility of coating failure is specified based on the reference information DB 161, and the number of rotations of the substrate W on which the coating film forming process is started under the specified first condition is controlled based on the imaging result and the reference information DB 161. As a result, coating failure of the substrate W can be further suppressed.

In addition, the fact that the first condition can be easily specified based on the reference information DB 161 as described above eliminates the need for a large number of substrates W and time for establishing an optimum condition without coating failure, and thus the cost can be reduced.

According to the coating processing apparatus and the coating processing method of the second embodiment, the same effects as those of the first embodiment are obtained.

### Modification

A modification of the second embodiment will be described. The modification of the second embodiment is a modification corresponding to the modification of the first embodiment. That is, the coating processing apparatus and the coating processing method according to the modification of the second embodiment are different from those of the second embodiment in that a new second discharge position RM is determined instead of the control of the number of rotations of the substrate W. In the following description, the description of the same configurations as those of the second embodiment described above may be omitted.

When the determination module 53 determines that the distance L falls within the predetermined range, the second condition determination module 54 determines the second discharge position RM so that the distance L is maintained within the predetermined range based on the analysis result of the calculation module 52 and the reference information DB 161.

For example, when the distance L transitions for each time, the second condition determination module 54 determines the position of the second discharge position RM as the second condition based on the state of the transition, and “spreading speed of first liquid film” and “spreading speed of second liquid film” in the reference information DB 161.

The second condition determination module 54 controls the nozzle drive mechanism 31 so that the second condition is applied to the second discharge position RM in the second and subsequent substrates W when a plurality of substrates W are processed with the same recipe.

As a result, since the distance L between the edge 122 and the edge 222 can be adjusted in advance, the distance L can be maintained in a predetermined range until the discharge of the resist liquid 100 is ended.

According to the coating processing apparatus and the coating processing method of the modification, the same effects as those of the coating processing apparatus and the coating processing method of the first and second embodiments are obtained.

### Other Modifications

In the embodiments and the modifications described above, description was made that one camera 40a and one camera 40b are provided on the side surfaces of the chemical liquid nozzles 30a and 30b, respectively. However, the number of installed cameras and the installation positions are not limited thereto. For example, only one camera capable of imaging the edge 122 of the first liquid film 120 and the edge 222 of the second liquid film 220 may be provided in the coating processing apparatus 1. Furthermore, for example, as long as the edge 122 and the edge 222 can be imaged, the camera 40a and the camera 40b may have any installation position of the processor 10.

In the above-described embodiment and modification, the number of rotations of the substrate W is controlled so that the distance L is maintained within the predetermined range, but the embodiments and modifications are not limited thereto. For example, the rotational acceleration of the substrate W may be controlled.

The first embodiment and the modification thereof, and the second embodiment and the modification thereof may be used in combination.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A coating processing apparatus comprising:
a rotary table that is rotatable while holding a substrate on which a coating film is to be formed;
a first discharge nozzle that discharges a first coating liquid to a first discharge position that is a central portion of the substrate held on the rotary table to form a first liquid film;
a second discharge nozzle that discharges a second coating liquid to a second discharge position outside the first discharge position of the substrate to form a second liquid film;
an imaging device configured to be able to image contours of the first and second liquid films spreading toward an outside of the substrate by rotation of the substrate; and
a control device configured to control at least one of a rotation speed of the substrate and the second discharge position based on an imaging result by the imaging device so that a distance between the contours falls within a predetermined range.

2. The coating processing apparatus according to claim 1, wherein
the control device includes a controller configured to calculate the distance between the contours of the first and second liquid films based on the imaging result to control at least one of the rotation speed of the substrate and the second discharge position so that the distance between the contours is maintained within the predetermined range when the distance between the contours is within the predetermined range.

3. The coating processing apparatus according to claim 2, wherein
the controller is configured to control, based on a transition of the distance between the contours from a first time after starting to discharge the first coating liquid to a second time after the first time, the rotation speed of the substrate after the second time and until the discharge of the first coating liquid is ended.

4. The coating processing apparatus according to claim 2, wherein
the controller is configured to control, based on a transition of the distance between the contours from a first time after starting to discharge the first coating liquid in the substrate held on the rotary table to a second time after the first time, the second discharge position on a substrate to be held on the rotary table after the substrate.

5. The coating processing apparatus according to claim 2, wherein
the controller is configured not to control the rotation speed of the substrate when the distance between the contours exceeds the predetermined range.

6. The coating processing apparatus according to claim 2, wherein
the control device further includes a storage unit configured to store reference information in which the rotation speed of the substrate, the second discharge position, the distance between the contours, a speed at which the first and second liquid films spread on the substrate, and an inspection result obtained by inspecting a formation state of the coating film are associated with each other for the substrate on which the coating film is formed, and
the controller is configured to control at least one of the rotation speed of the substrate and the second discharge position so that the distance between the contours falls within the predetermined range, based on the reference information and the imaging result.

7. The coating processing apparatus according to claim 6, wherein
the controller is further configured to:
determine, based on the reference information, the second discharge position and the rotation speed of the substrate when the formation state of the coating film satisfies a predetermined condition, as a condition for starting formation of the first and second liquid films; and
control at least one of the rotation speed of the substrate and the second discharge position so that the distance between the contours falls within the predetermined range, based on the speed included in the reference information at which the first and second liquid films spread on the substrate and the imaging result obtained by imaging the contours of the first and second liquid films formed using the condition.

8. The coating processing apparatus according to claim 7, wherein
the controller is configured to control, based on the distance between the contours from a first time after starting to discharge the first coating liquid to a second time after the first time and the speed included in the reference information at which the first and second liquid films spread on the substrate, the rotation speed of the substrate after the second time and until the discharge of the first coating liquid is ended.

9. The coating processing apparatus according to claim 7, wherein
the controller is configured to control, based on the distance between the contours from a first time after starting to discharge the first coating liquid to a second time after the first time and the speed included in the reference information at which the first and second liquid films spread on the substrate, in the substrate held on the rotary table, the second discharge position on a substrate to be held on the rotary table after the substrate.

10. The coating processing apparatus according to claim 1, wherein
the imaging device includes first and second imaging devices respectively provided in the first discharge nozzle and the second discharge nozzle, and
the first imaging device included in the first discharge nozzle and the second imaging device included in the second discharge nozzle image the respective contours of the first and second liquid films.

11. The coating processing apparatus according to claim 1, wherein
the imaging device includes one imaging device provided to be able to image the contours of the first and second liquid films.

12. The coating processing apparatus according to claim 1, wherein
the contour of the second liquid film includes an edge inside the second liquid film formed in a substantially annular shape on the substrate.

13. The coating processing apparatus according to claim 1, wherein
the predetermined range is equal to or more than a distance at which the contours of the first and second liquid films do not contact with each other and equal to or less than 4 cm.

14. The coating processing apparatus according to claim 1, wherein
the first coating liquid includes photoresist, and
the second coating liquid includes thinner capable of dissolving the photoresist.

15. A method for forming a coating film, the method comprising:
holding a substrate on which a coating film is to be formed to hold the substrate on a rotary table that is rotatable;
discharging a first coating liquid to a first discharge position that is a central portion of the substrate to form a first liquid film;
discharging a second coating liquid to a second discharge position outside the first discharge position of the substrate to form a second liquid film;
imaging contours of the first and second liquid films spreading toward an outside of the substrate by rotation of the substrate by an imaging device; and
controlling at least one of a rotation speed of the substrate and the second discharge position based on an imaging result by the imaging device so that a distance between the contours falls within a predetermined range.

16. The method for forming the coating film according to claim 15, further comprising:
calculating the distance between the contours of the first and second liquid films based on the imaging result by the imaging device to control at least one of the rotation speed of the substrate and the second discharge position so that the distance between the contours is maintained within the predetermined range when the distance between the contours is within the predetermined range.

17. The method for forming the coating film according to claim 16, further comprising:
calculating the distance between the contours based on the imaging result from a first time after starting to discharge the first coating liquid to a second time after the first time to control the rotation speed of the substrate after the second time and until the discharge of the first coating liquid is ended based on a transition of the distance between the contours.

18. The method for forming the coating film according to claim 16, further comprising:
calculating the distance between the contours based on the imaging result from a first time after starting to discharge the first coating liquid in the substrate held on the rotary table to a second time after the first time to control the second discharge position on a substrate to be held on the rotary table after the substrate based on a transition of the distance between the contours.

19. The method for forming the coating film according to claim 16, further comprising:
not controlling the rotation speed of the substrate when the distance between the contours exceeds the predetermined range.

20. The method for forming the coating film according to claim 16, the method being executed by a coating processing apparatus controlled by a control device including a storage unit, the method further comprising:
causing the storage unit to store reference information in which the rotation speed of the substrate, the second discharge position, the distance between the contours, a speed at which the first and second liquid films spread on the substrate, and an inspection result obtained by inspecting a formation state of the coating film are associated with each other for the substrate on which the coating film is formed; and
controlling at least one of the rotation speed of the substrate and the second discharge position so that the distance between the contours falls within the predetermined range based on the reference information and the imaging result.
